(19) United States
(12) Patent Application Publication
(10) Pub. No.: US 2005/0183686 A1
(43) Pub. Date: Aug. 25, 2005

(54) Hydraulic lash adjuster

(76) Inventors: Hiroki Fujii, Chita-gun (JP); Shizuo Ishikawa, Nishio-shi (JP); Mitsuyoshi Teramura, Toyota-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/784,961

(22) Filed: Feb. 25, 2004

(51) Int. Cl. H01L 27/15; F01L 1/14; H01L 29/26; F01L 1/18

(52) U.S. Cl. 123/90.58; 123/90.53; 123/90.55

(57) ABSTRACT

A hydraulic lash adjuster for an internal combustion engine is disclosed. The hydraulic lash adjuster includes a low-pressure chamber defined in the plunger and filled with a hydraulic fluid and a high-pressure chamber filled with hydraulic fluid defined in a lower interior of the cylinder and partitioned by the bottom wall of the plunger from the low-pressure chamber. A valve port is formed through the bottom wall of the plunger so as to communicate with both the low-pressure and high-pressure chambers. The valve port has at the high-pressure chamber side an opening edge formed with a valve seat face. A valve element is provided in the high-pressure chamber so as to abut and depart from the valve seat face, thereby closing and opening the valve port. The valve element is made of a material having a specific gravity smaller than steel.

### BACKGROUND OF THE INVENTION

1. Field of the Invention

This invention relates to a hydraulic lash adjuster used in valve gears or valve mechanisms for internal combustion engines.

2. Description of the Related Art

A conventional hydraulic lash adjuster comprises a bottomed cylinder fixed to a cylinder head and a plunger accommodated in the cylinder so as to be vertically moved. The plunger has an upper end protruding from the cylinder. A rocker arm is supported on the upper end of the plunger. The interior of the plunger serves as a low-pressure chamber. A lower interior of the cylinder is divided by a bottom wall of the plunger, thereby serving as a high-pressure chamber. The bottom wall of the plunger is formed with a valve port of a check valve. The low-pressure chamber is filled with a hydraulic fluid supplied from a fluid supply passage via communication holes formed in the circumferential walls of the respective cylinder and plunger. Further, the high-pressure chamber is filled with the hydraulic fluid supplied via the valve port of the check valve.

A spherical valve element is accommodated in the high-pressure chamber and is biased in such a direction that it closes the valve port. The valve element and valve port constitute a check valve. When the side of the rocker arm applies a downward pressing force to the plunger, the valve port is closed by the valve element such that the high-pressure chamber is tightly closed, whereupon the hydraulic fluid filling the high-pressure chamber prevents the plunger from moving downward. Further, when the plunger is moved upward such that the volume of the high-pressure chamber is increased and the pressure reduced, the valve element is moved downward relative to the plunger, thereby opening the valve port. As a result, the hydraulic fluid flows from the low-pressure chamber into the high-pressure chamber, so that the interior of the high-pressure chamber remains filled with the hydraulic fluid. For example, JP-A-5-288020 discloses one of hydraulic lash adjusters of the above-described type.

In the above-noted lash adjuster provided with the check valve, the valve element collides against a valve seat face of the valve port every time the valve element opens or closes the valve port. The valve element is made of a steel having a large specific gravity, for example, SUJ2, in the conventional lash adjuster. Accordingly, when the collision of the valve element is reiterated many times during the operation of the engine, there is a possibility that the valve seat face may be worn out or the valve element may bite into the valve seat face thereby inhibiting the free movement of the valve element.

### SUMMARY OF THE INVENTION

Therefore, an object of the present invention is to provide a lash adjuster in which the wear of the valve seat face can be reduced and the valve element can be prevented from being caught by or adhered to the valve seat face.

The present invention provides a hydraulic lash adjuster for an internal combustion engine including a cylinder head and a rocker arm. The hydraulic lash adjuster comprising a bottomed cylinder fixed to the cylinder head, a plunger having a bottom wall and an upper end supporting the rocker arm, the plunger being vertically movable while being brought into sliding contact with an inner circumferential face of the cylinder, a low-pressure chamber defined in the plunger and filled with a hydraulic fluid, a high-pressure chamber defined in a lower interior of the cylinder and partitioned by the bottom wall of the plunger from the low-pressure chamber, the high-pressure chamber also being filled with hydraulic fluid, a valve port formed through the bottom wall of the plunger so as to communicate with both the low-pressure and high-pressure chambers therebetween. The valve port having at the high-pressure chamber side an opening edge formed with a valve seat face and a valve element provided in the high-pressure chamber so as to abut and depart from the valve seat face, thereby closing and opening the valve port. In this construction, the valve element is made of a material having a specific gravity smaller than steel.

The valve element in the above-described construction has a smaller specific gravity than the conventionally used valve element of a steel ball. Accordingly, the inertial mass of the valve element in a collision against the valve seat face is also reduced. Consequently, the wear of the valve seat face due to the collision of the valve element against the valve seat face can be reduced, and the valve element can be prevented from biting into the valve seat face thereby being caught by, stuck, or otherwise adhered to the valve seat face, inhibiting the free movement of the valve element.

In a preferred form, the valve element is made of a ceramic containing silicon nitride. The valve element thus has a higher hardness as compared with the conventionally used valve element and accordingly, the valve element can be prevented from being broken or deformed when colliding against the valve seat face. Consequently, the valve element can fulfil its functions sufficiently and reliably over a relatively longer lifetime.

### BRIEF DESCRIPTION OF THE DRAWINGS

Other objects, features and advantages of the present invention will become clear upon reviewing the following description of the embodiment with reference to the accompanying drawings, in which:

FIG. 1 is a longitudinal section of the lash adjuster in accordance with one embodiment of the invention, showing the lash adjuster mounted on the cylinder head;

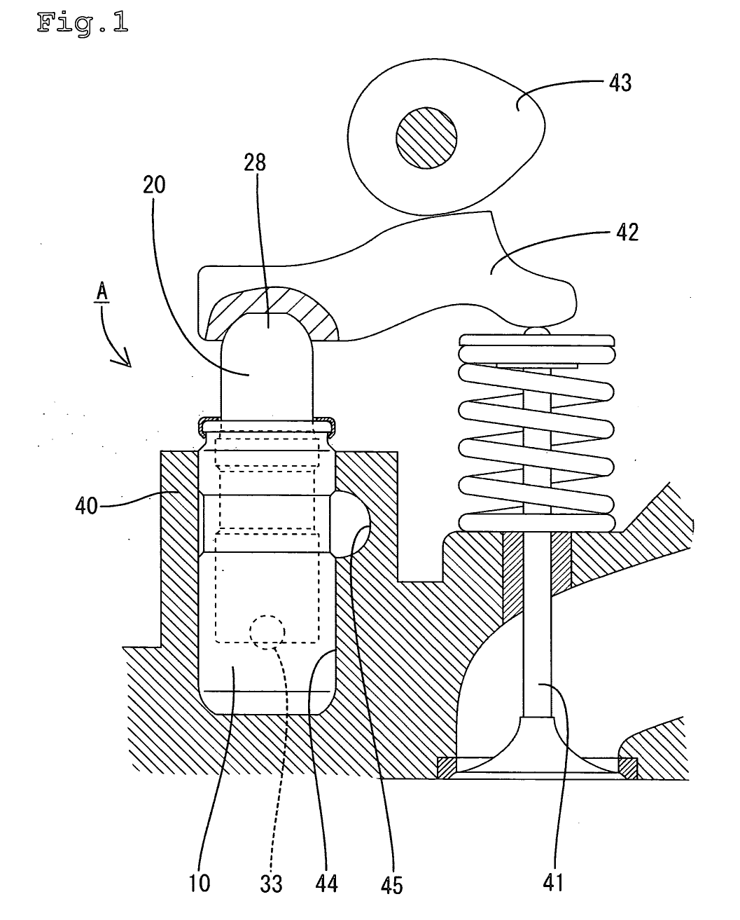

FIG. 2 is a longitudinal section of the lash adjuster;

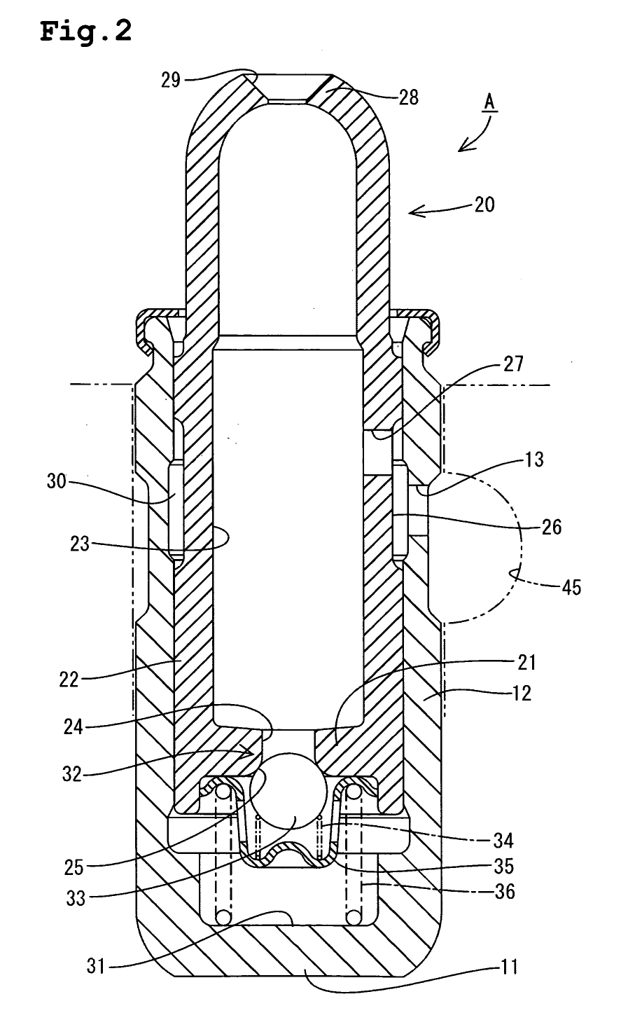

FIG. 3 is an enlarged section of the valve element closing the valve port; and

FIG. 4 is an enlarged section of the valve element opening the valve port.

### DETAILED DESCRIPTION OF THE INVENTION

One embodiment of the present invention will be described with reference to the accompanying drawings. The hydraulic lash adjuster A, in accordance with the embodiment, is applied to a valve gear for an internal combustion engine. The valve gear will firstly be described. The valve gear comprises a valve 41, the lash adjuster A, a rocker arm 42 and a cam 43. With the rotation of the cam 43, the rocker arm 42 vertically oscillates with an upper end of the lash adjuster A serving as a fulcrum, thereby vertically moving the valve 41, as is well known in the art.

The lash adjuster will now be described. The lash adjuster A comprises a cylinder 10 and a plunger 20. The cylinder 10 is formed into the shape of a bottomed cylinder and includes a generally circular bottom wall 11 and a generally cylindrical circumferential wall 12 extending from a circumferential edge of the bottom wall 11. The cylinder 10 is fixed in a mounting hole 44, opening in an upper face of a cylinder head 40. The circumferential wall 12 of the cylinder 10 has a communication hole 13 extending therethrough. The communication hole 13 communicates with a hydraulic fluid supply passage 45 provided in the cylinder head 40.

The plunger 20 is also formed into the shape of a bottomed cylinder and includes a generally circular bottom wall 21 and a generally cylindrical circumferential wall 22 extending from a circumferential edge of the bottom wall 21. An interior of the plunger 20 serves as a low-pressure chamber 23. The bottom wall 21 of the plunger 20 has a centrally located circular valve port 24 vertically extending therethrough. The valve port 24 has a valve seat face 25 formed on a lower (or high-pressure chamber 31 side, as will be described later) opening edge. The valve seat face 25 comprises a reverse tapered face or an arcuate face (a rounded face). The circumferential wall 22 of the plunger 20 has a reduced portion 26 formed in an outer circumference thereof. The reduced portion 26 has an inner communication hole 27 extending through the circumferential wall 22. The plunger 20 has an upper end formed with a generally semispherical (or dome-like) support 28. The rocker arm 42 abuts an outer face of the support 28 from above so that an oscillation fulcrum of the rocker arm 42 is supported on the support 28. The support 28 has a circular vent hole 29 which is formed in a central top thereof so as to extend vertically therethrough.

The plunger 20 is fitted in the cylinder 10 and vertically moved while the circumferential face of the plunger 20 is in sliding contact with the circumferential face of the cylinder 10. Further, a circumferential communication passage 30 is defined between the reduced portion 26 of the plunger 20 and the inner circumferential face of the cylinder 10. The communication passage 30 communicates with both of the outer and inner communication holes 13 and 27.

A high-pressure chamber 31 is defined in the lower interior portion of the cylinder 10 and partitioned from the low-pressure chamber 23 by the bottom wall 21 of the plunger 20. A spherical valve element 33 is provided in the high-pressure chamber 31. The valve port 24 and the valve element 33 constitute a check valve 32. The valve element 33 is biased by a first spring 34 in such a direction that it closes the valve port 24 (upward). The valve element 33 is enclosed in a ball-cage 35, and the first spring 34 is disposed between the ball-cage 35 and the valve element 33. Further, a second spring 36 is provided between the ball-cage 35 and the bottom of the cylinder 10. The second spring 36 urges both of the plunger 20 and ball-cage 35 upward. A hydraulic fluid is supplied sequentially through the hydraulic fluid supply passage 45 of cylinder head 40, the outer communication hole 13, the communication passage 30, and the inner communication hole 27, being then stored in the low-pressure chamber 23. The hydraulic fluid stored in the low-pressure chamber 23 is further supplied through the valve port 24 into the high-pressure chamber 31.

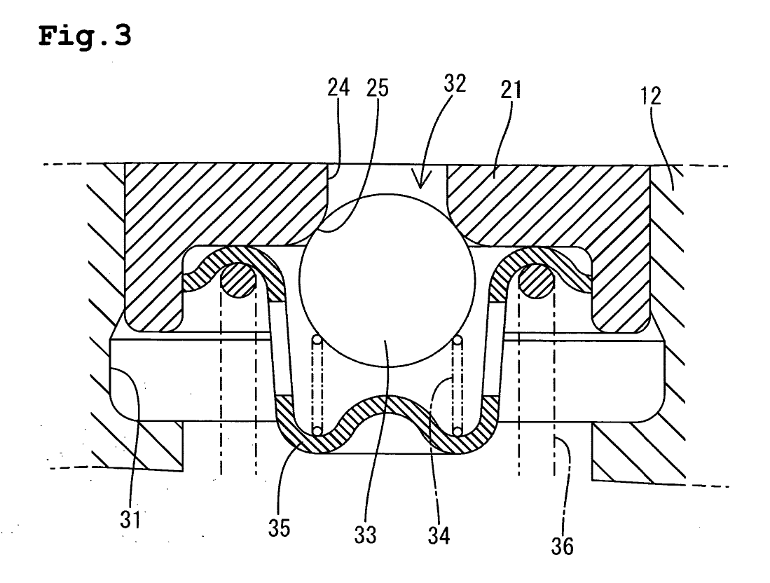

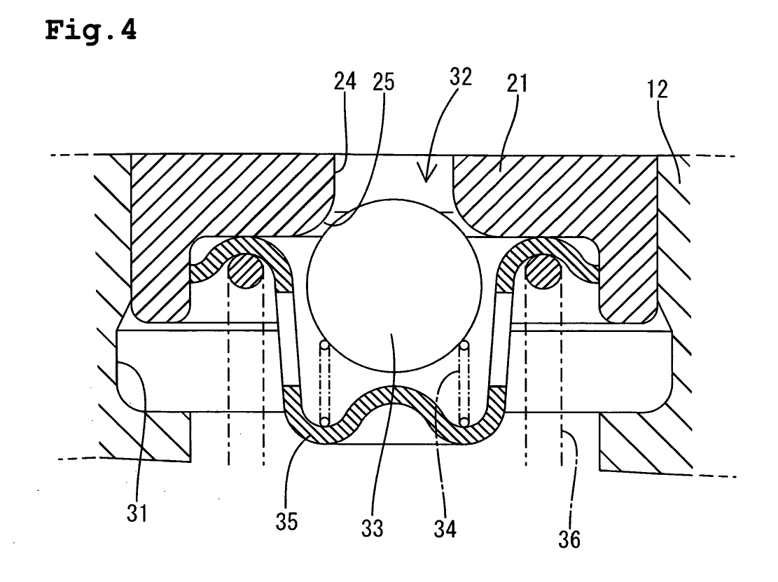

When the side of the rocker arm 42 applies a downward pressing force to the plunger 20, the valve port 24 is closed by the valve element 33 such that the high-pressure chamber 31 is tightly closed, whereupon the hydraulic fluid filling the high-pressure chamber 31 prevents the plunger 20 from moving downward. See FIG. 3. Further, when the plunger 20 is moved upward such that the volume of the high-pressure chamber 31 is increased and the pressure is reduced, the valve element 33 is moved downward relative to the plunger 20 to depart from the valve seat face 25, thereby opening the valve port 24. See FIG. 4. As a result, the hydraulic fluid flows from the low-pressure chamber 23 into the high-pressure chamber 31, so that the interior of the high-pressure chamber 31 remains filled with the hydraulic fluid. Upon the stopping of the upward movement of the plunger 20, the valve element 33 is urged by the first spring 34to abut the valve seat face 25, whereby the valve port 24 is closed. As a result, the high-pressure chamber 31 is filled with the hydraulic fluid and tightly closed.

In the check valve 32, the valve element 33 collides against the valve seat face 25 of the valve port 24 each time during the opening or closing of the valve port 24. In the prior art, the valve element is made of a steel having a large specific gravity, for example, SUJ2. Accordingly, when the collision of the valve element is reiterated many times during the operation of the engine, there is a possibility that the valve seat face may be worn out or the valve element may bite into the valve seat face thereby inhibiting the free movement of the valve element.

In view of the above-noted problem, the valve element 33 is made of a ceramic containing silicon nitride in the embodiment, instead of the steel ball. The valve element 33 made of the silicon nitride containing ceramic has a higher hardness as compared with the conventionally used valve element and accordingly, the valve element 33 can be prevented from being broken or deformed when colliding against the valve seat face 25. Consequently, the valve element 33 can fulfil its functions sufficiently and reliably over a relatively longer lifetime.

Furthermore, the ceramic valve element 33 has a smaller specific gravity than the conventional valve element of steel ball and accordingly, the inertial mass of the valve element 33 in the collision against the valve seat face 25 is also reduced. Consequently, the wear of the valve seat face 25 due to the collision of the valve element 33 against the valve seat face 25 can be reduced, and the valve element 33 can be prevented from biting into the valve seat face 25 thereby being caught by or adhered to the valve seat face 25.

Mechanical characteristics of the silicon nitride containing ceramic made into the valve element 33 of the lash adjuster A are as follows. The silicon nitride ceramic has a specific gravity of 3.2, a hardness of 1500 [HV], a linear expansion coefficient of 3.2×10⁻⁶ [1/□], and a heat-resistant temperature of 800 [□]. For the sake of comparison, the conventional steel ball (SUJ2) has a specific gravity of 7.8, a hardness of 750 [HV], a linear expansion coefficient of 12.5×10⁻⁶ [1/□], and a heat-resistant temperature of 180 [□].

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

1-2. (canceled)

3. A hydraulic lash adjuster for an internal combustion engine including a cylinder head and a rocker arm, the hydraulic lash adjuster comprising:
a bottomed cylinder fixed to the cylinder head;
a plunger having a bottom wall and an upper end supporting the rocker arm, the plunger being vertically movable while being brought into sliding contact with an inner circumferential face of the cylinder;
a low-pressure chamber defined in the plunger and filled with a hydraulic fluid;
a high-pressure chamber defined in a lower interior of the cylinder and partitioned by the bottom wall of the plunger from the low-pressure chamber, the high-pressure chamber being filled with the hydraulic fluid;
a valve port formed through the bottom wall of the plunger so as to communicate with the low-pressure chamber and the high-pressure chamber, the valve port having at the high-pressure chamber side an opening edge formed with a valve seat face; and
a valve element provided in the high-pressure chamber so as to abut and depart from the valve seat face, thereby closing and opening the valve port,
wherein the valve seat face is a convex and arcuate face.

4. The hydraulic lash adjuster according to claim 3, wherein the valve element is made of a material with a specific gravity in the range between hydraulic fluid and steel.

5. The hydraulic lash adjuster according to claim 3, wherein the valve element is made of a ceramic containing silicon nitride.

6. The hydraulic lash adjuster according to claim 3, wherein the valve element is biased in the closing direction by a spring element.

7. The hydraulic lash adjuster according to claim 6, wherein the spring element biasing the valve element in the closing direction comprises a first spring element and a second spring element.
